(19) United States
(12) Patent Application Publication
(10) Pub. No.: US 2022/0391564 A1
(43) Pub. Date: Dec. 8, 2022

(54) SIMULATION FRAMEWORK FOR REAL TIME VEHICLE DISPATCHING ALGORITHMS EVALUATION

(71) Applicant: Beijing DiDi Infinity Technology and Development Co., Ltd., Beijing (CN)

(72) Inventors: Fan ZHANG, BEIJING (CN); Xiaocheng TANG, SAN MATEO, CA (US); Zhiwei QIN, SAN JOSE, CA (US); Hongtu ZHU, BEIJING (CN)

(21) Appl. No.: 17/337,127

(22) Filed: Jun. 2, 2021

(51) Int. Cl. G06F 30/27; G06N 5/00; G06N 20/20; G06Q 50/30; G06Q 10/06

(52) U.S. Cl. CPC G06F 30/27; G06N 5/003; G06N 20/20; G06Q 50/30; G06Q 10/0633; G06Q 10/0631

(57) ABSTRACT

Systems, methods, and non-transitory computer-readable media can construct a simulation framework for a ride sharing service. The simulation framework comprises a simulation environment and an agent comprising one or more algorithms including an order dispatching algorithm and a driver reposition algorithm. One or more states of the simulation environment include information about a plurality of drivers and a plurality of trip order requests, and can be provided to the agent. One or more actions from the agent can be obtained. The one or more actions comprises at least one of: a plurality of matches between the plurality of drivers and the plurality of trip order requests, or a plurality of reposition destinations for a subset of the plurality of drivers. The one or more states of the simulation environment can be updated based on the one or more actions.

### FIELD OF THE INVENTION

This disclosure generally relates to a method and system for providing a simulation framework for evaluating decision-making algorithms for ride-hailing platforms, such as order dispatching algorithms and/or vehicle repositioning algorithms.

### BACKGROUND

A ride-hailing platform can automatically allocate transportation requests to vehicles for providing transportation services. The efficiency of the ride-hailing platform mainly depends on how well vehicles and order requests are aligned in both spatial and temporal spaces. Considering the high impact of deploying vehicle dispatching algorithms online and the high cost of evaluating the performance of these algorithms on a real vehicle dispatching platform, there is an urgent need for a simulation environment for performing realistic and comprehensive evaluation of algorithms.

### SUMMARY

In one aspect of the present disclosure, in various implementations, a method may include constructing, by a computer system, a simulation framework for a ride sharing service, the simulation framework comprising a simulation environment and an agent. The agent comprises one or more algorithms including an order dispatching algorithm and a driver reposition algorithm. The method may also include providing, by the computer system, one or more states of the simulation environment to the agent during a first time window. The one or more states include information about a plurality of drivers and a plurality of trip order requests. The method may further include obtaining, by the computer system, one or more actions from the agent during the first time window. The one or more actions comprise at least one of: a plurality of matches between the plurality of drivers and the plurality of trip order requests obtained from the order dispatching algorithm, or a plurality of reposition destinations for a subset of the plurality of drivers obtained from the driver reposition algorithm. The method may furthermore include updating, by the computer system, the one or more states of the simulation environment based on the one or more actions during the first time window.

In another aspect of the present disclosure, a computer system may comprise at least one processor and a memory storing instructions that, when executed by the at least one processor, cause the computer system to perform operations. The operations may include constructing a simulation framework for a ride sharing service, the simulation framework comprising a simulation environment and an agent. The agent comprises one or more algorithms including an order dispatching algorithm and a driver reposition algorithm. The operations may also include providing one or more states of the simulation environment to the agent during a first time window. The one or more states include information about a plurality of drivers and a plurality of trip order requests. The operations may further include obtaining one or more actions from the agent during the first time window. The one or more actions comprise at least one of: a plurality of matches between the plurality of drivers and the plurality of trip order requests obtained from the order dispatching algorithm, or a plurality of reposition destinations for a subset of the plurality of drivers obtained from the driver reposition algorithm. The operations may furthermore include updating the one or more states of the simulation environment based on the one or more actions during the first time window.

Yet another aspect of the present disclosure is directed to a non-transitory computer-readable storage medium including instructions that, when executed by at least one processor of a computer system, cause the computer system to perform operations. The operations may include constructing a simulation framework for a ride sharing service, the simulation framework comprising a simulation environment and an agent. The agent comprises one or more algorithms including an order dispatching algorithm and a driver reposition algorithm. The operations may also include providing one or more states of the simulation environment to the agent during a first time window. The one or more states include information about a plurality of drivers and a plurality of trip order requests. The operations may further include obtaining one or more actions from the agent during the first time window. The one or more actions comprise at least one of: a plurality of matches between the plurality of drivers and the plurality of trip order requests obtained from the order dispatching algorithm, or a plurality of reposition destinations for a subset of the plurality of drivers obtained from the driver reposition algorithm. The operations may furthermore include updating the one or more states of the simulation environment based on the one or more actions during the first time window.

In some embodiments, the method further comprises iterating, by the computer system, the providing the one or more states of the simulation environment to the agent, the obtaining the one or more actions from the agent, and the updating the one or more states during a second time window.

In some embodiments, the method further comprises initializing, by the computer system, the simulation environment during the first time window. The initializing comprises initializing a driver distribution of the plurality of drivers in a geographical area at a starting time of the first time window.

In some embodiments, the method further comprises evaluating, by the computer system, performance of the one or more algorithms. The evaluating comprises at least one of: determining a score for the order dispatching algorithm based on a mean total GMV (Gross Merchandise Value) of successful completed orders per unit time over a period of time; or determining a score for the driver reposition algorithm based on a mean individual income rate for a group of drivers over a period of time.

In some embodiments, the simulation environment includes historical real data and a set of user behavior models trained based on the historical real data. The set of user behavior models comprises a driver movement model, a driver online-offline model, and a rider trip cancellation model.

In some embodiments, the updating the one or more states of the simulation environment further comprises: predicting, by the computer system, whether a matched order will be canceled based on the rider trip cancellation model; predicting, by the computer system, a destination of an idle driver based on the driver movement model and statistics of historical driver movement; and updating, by the computer system, the information about the plurality of idle drivers and the plurality of trip order requests.

In some embodiments, the driver movement model is a tree-based machine learning model.

In some embodiments, the driver online-offline model is a machine learning model trained based on a number of historical online drivers, a number of historical offline drivers, and a number of simulated offline drivers.

In some embodiments, the rider trip cancellation model is a machine learning model trained to predict a cancellation probability of an order based on order features. The order features include at least one of: a start location of the order, a destination of the order, a current time of the order, a day of the week of the order, or a price quote for the order.

In some embodiments, the method further comprises training the rider trip cancellation model based on training data generated based on a plurality of historical canceled orders and a plurality of successfully completed orders.

In some embodiments, the rider trip cancellation model is a LightGBM (Light Gradient Boosting Machine) decision tree model.

These and other features of the methods, systems, and non-transitory computer readable media disclosed herein, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for purposes of illustration and description only and are not intended as a definition of the limits of the invention. It is to be understood that the foregoing general description and the following detailed description are exemplary and explanatory only, and are not restrictive of the invention, as claimed.

### BRIEF DESCRIPTION OF THE DRAWINGS

Preferred and non-limiting embodiments of the invention may be more readily understood by referring to the accompanying drawings in which:

FIG. 1 illustrates an example environment for a ridesharing platform system, in accordance with various embodiments of the disclosure.

FIG. 2 illustrates an example system diagram of a simulation framework for real time vehicle dispatching algorithms evaluation, in accordance with various embodiments of the disclosure.

FIG. 3 illustrates an example workflow of the simulation framework for real time vehicle dispatching algorithms evaluation, in accordance with various embodiments of the disclosure.

FIG. 4A illustrates a flowchart of an example method for driver movement prediction, in accordance with various embodiments of the disclosure.

FIG. 4B illustrates a flowchart of an example method for destination prediction of an idle driver, in accordance with various embodiments of the disclosure.

FIG. 5 illustrates a flowchart of an example method for simulation framework construction, in accordance with various embodiments of the disclosure.

FIG. 6 illustrates a block diagram of an example computer system in which any of the embodiments described herein may be implemented.

### DETAILED DESCRIPTION

Specific, non-limiting embodiments of the present invention will now be described with reference to the drawings. It is to be understood that features and aspects of any embodiment disclosed herein may be used and/or combined with features and aspects of any other embodiment disclosed herein. It should also be understood that such embodiments are by way of example and are merely illustrative of a small number of embodiments within the scope of the present invention. Various changes and modifications obvious to one skilled in the art to which the present invention pertains are deemed within the spirit, scope, and contemplation of the present invention as further defined in the appended claims.

Various embodiments of the present disclosure include systems, methods, and non-transitory computer readable media configured to provide a simulation framework for evaluating the performance of an order dispatching algorithm and/or a driver reposition algorithm. The simulation framework is composed of two components: a simulation environment (also referred to as “simulator”) and an agent. The simulator is responsible for building a virtual environment to test the algorithms, while the agent is responsible for implementing the algorithms. The simulator periodically sends states of the simulation environment to the agent, receives actions from the agent, and updates the states of the simulation environment. The states of the simulation environment include information about drivers and order requests. The actions include outputs from the order dispatching and/or the driver reposition algorithms. The interaction between the simulator and the agent is iterated until the simulation is stopped.

The order dispatching algorithm and the vehicle repositioning algorithm manage a supply of drivers and a demand for transportation services, and aim to increase drivers' income as well as the vehicle dispatching platform's revenue. The performance benchmarks of these two algorithms can be based on the income or revenue generated from the transportation services. These two algorithms can be tested in the simulation framework before being rolled out to live production services. The simulation framework builds a simulated world with drivers and riders, and mimics real-world scenarios by learning from historical data, thereby allows engineers and data scientists to rapidly prototype and test algorithms in a risk-free environment.

Passenger, Driver, and Ridesharing Platform System

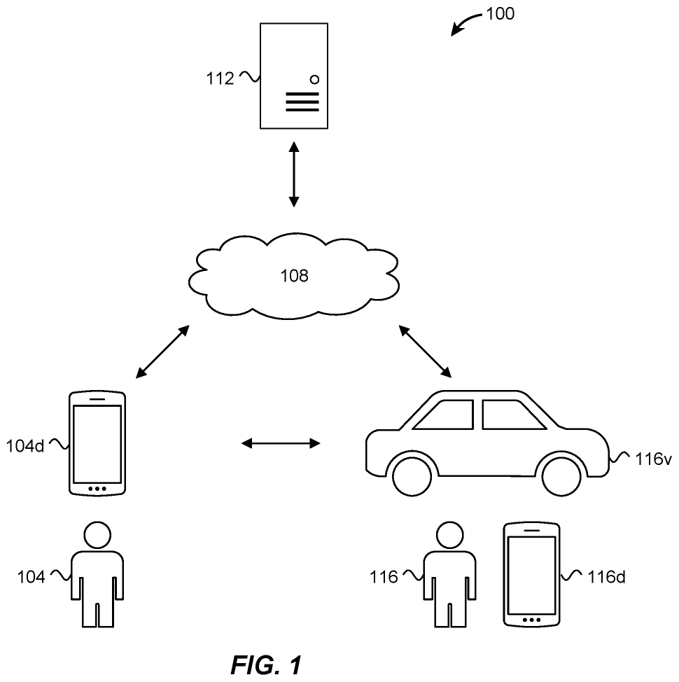

FIG. 1 illustrates an example environment for a ridesharing platform system. In the environment 100 illustrated in FIG. 1, a passenger 104 uses a passenger device 104d (e.g., a smartphone, a tablet, or a computer) to make a trip request, via a communication network 108 (e.g., the Internet) to a ridesharing platform system 112. The ridesharing platform system 112 can assign a driver 116 and the driver's vehicle 116v (e.g., a car, an SUV, and a truck) to fulfill the trip request. The driver 116 can receive and accept or decline the trip request using a driver device 116d (e.g., a smartphone, a tablet, or a computer). The driver device 116d can be a standalone device or part of the driver's vehicle 116v.

During an onboarding process, the passenger 104 and the driver 116 can provide personal information to the ridesharing platform system 112. Stringent background checks can increase driver safety and passenger safety. The passenger 104 can provide the ridesharing platform system 112 with a pickup or starting location and a drop off or destination location of a trip and receive pricing information (e.g., the estimated cost of the trip) and time information (e.g. the estimated duration of the trip). If the pricing information and time information are acceptable to the passenger 104, the passenger 104 can make a trip request or place an order (e.g., by clicking an order button) to the ridesharing platform system 112. After receiving the trip request from the passenger 104, the ridesharing platform system 112 can decide whether to accept the trip request and assign or match the driver 116 to the passenger for the trip request. Declining or rejecting a trip request of a passenger determined to be likely an offender in an incident can increase driver safety. The driver 116 can proceed to and arrive at the pickup location, where the passenger 104 can enter the driver's vehicle 116v and be transported, by the driver 116 using the vehicle 116v, to the drop off location of the trip request or order. The passenger 104 can pay (e.g., with cash or via the ridesharing platform system 112) the driver 116 after arrival at the drop off location.

Using the passenger device 104d, the passenger 104 can interact with the ridesharing platform system 112 and request ridesharing services. For example, the passenger 140, using the passenger device 104d, can make a trip request to the ridesharing platform system 112. A trip request can include rider identification information, the number of passengers for the trip, a requested type of the provider (e.g., a vehicle type or service option identifier), the pickup location (e.g., a user-specified location, or a current location of the passenger device 104d as determined using, for example, a global positioning system (GPS) receiver), and/or the destination for the trip.

The passenger device 104d can interact with the ridesharing platform system 112 through a client application configured to interact with the ridesharing platform system 112. The client application can present information, using a user interface, received from the ridesharing platform system 112 and transmit information to the ridesharing platform system 112. The information presented on the user interface can include driver-related information, such as driver identity, driver vehicle information, driver vehicle location, and driver estimated arrival. The information presented on the user interface can include the drop off location, a route from the pickup location to the drop off location, an estimated trip duration, an estimated trip cost, and current traffic condition. The passenger device 104d can include a location sensor, such as a global positioning system (GPS) receiver, that can determine the current location of the passenger device 104d. The user interface presented by the client application can include the current location of the passenger device 104. The information transmitted can include a trip request, a pickup location, and a drop off location.

The ridesharing platform system 112 can allow the passenger 104 to specify parameters for the trip specified in the trip request, such as a vehicle type, a pick-up location, a trip destination, a target trip price, and/or a departure timeframe for the trip. The ridesharing platform system 112 can determine whether to accept or reject the trip request and, if so, assign or attempt to assign the driver 116 with the driver vehicle 116v and the driver device 116d to the passenger 104 and the passenger's trip request. For example, the ridesharing platform system 112 can receive a trip request from the passenger device 104d, select a driver from a pool of available drivers to provide the trip, and transmit an assignment request to the selected driver's device 116d.

The driver 116 can interact with, via the driver device 116d, the ridesharing platform system 112 to receive an assignment request to fulfill the trip request. The driver can decide to start receiving assignment requests by going online (e.g., launching a driver application and/or providing input on the driver application to indicate that the driver is receiving assignments), and stop receiving assignment requests by going offline. The driver 116 can receive, from the ridesharing platform system 112, an assignment request to fulfill a trip request made by the passenger using the passenger device 104d to the ridesharing platform system 112. The driver 116 can, using the driver device 116d, accept or reject the assignment request. By accepting the assignment request, the driver 116 and the driver's vehicle 116v are assigned to the particular trip of the passenger 104 and are provided the passenger's pickup location and trip destination.

The driver device 116d can interact with the ridesharing platform system 112 through a client application configured to interact with the ridesharing platform system 112. The client application can present information, using a user interface, received from the ridesharing platform system 112 (e.g., an assignment request, a pickup location, a drop off location, a route from the pickup location to the drop off location, an estimated trip duration, current traffic condition, and passenger-related information, such as passenger name and gender) and transmit information to the ridesharing platform system 112 (e.g., an acceptance of an assignment request). The driver device 116d can include a location sensor, such as a global positioning system (GPS) receiver, that can determine the current location of the driver device 116d. The user interface presented by the client application can include the current location of the driver device 116 and a route from the current location of the driver device 116 to the pickup location. After accepting the assignment, the driver 116, using the driver's vehicle 116v, can proceed to the pickup location of the trip request to pick up the passenger 104.

The passenger device 104d and the driver device 116d can communicate with the ridesharing platform system 112 via the network 108 can include one or more local area and wide area networks employing wired and/or wireless communication technologies (e.g., 3G, 4G, and 5G), one or more communication protocols (e.g., transmission control protocol/Internet protocol (TCP/IP) and hypertext transport protocol (HTTP)), and one or more formats (e.g., hypertext markup language (HTML) and extensible markup language (XML).

Simulation Framework for Vehicle Dispatching Algorithms Evaluation

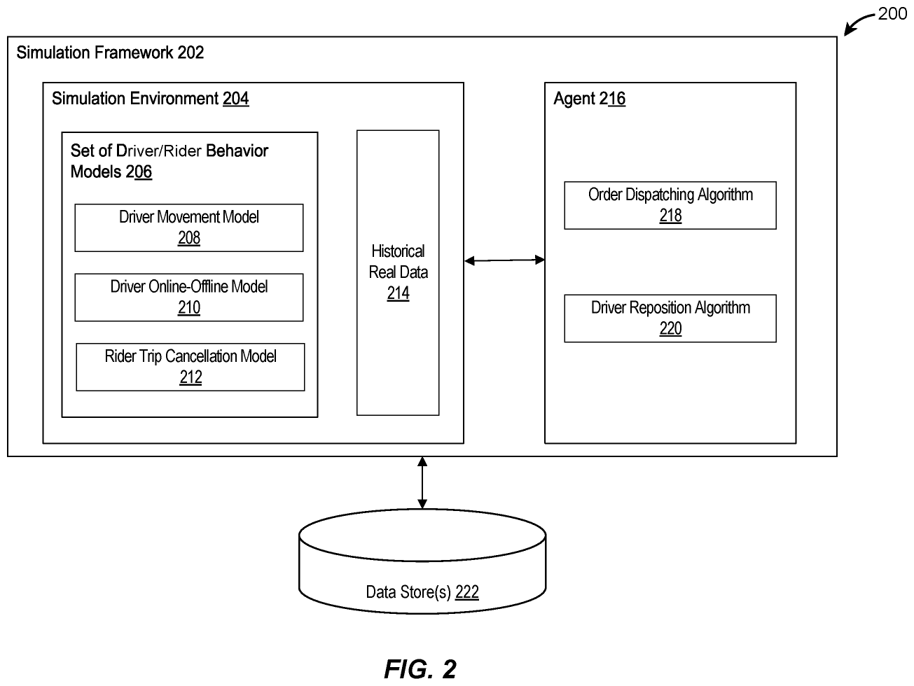

FIG. 2 illustrates an example system diagram of a simulation framework for real time vehicle dispatching algorithms evaluation, in accordance with various embodiments of the disclosure. The example system 200 includes a simulation framework 202 for an evaluation of real time order dispatching and driver reposition algorithms. The simulation framework 202 can be configured to communicate and/or operate with the at least one data store 222. The data store 222 can be configured to store and maintain various types of data. In some embodiments, the data store 222 can store information that is utilized by the simulation framework 202. It is contemplated that there can be many variations or other possibilities.

In some embodiments, the simulation framework 202 can include a simulation environment 204 and an agent 216. The simulation environment 204 is configured to build a virtual environment to simulate driver-rider interactions and evaluate algorithms. The agent 216 is configured to implement the algorithms to be evaluated, such as an order dispatching algorithm 218 and a driver reposition algorithm 220. The simulation environment 204 periodically sends states of the simulation environment 204 to the agent 216, and receives actions (i.e., order dispatching and driver reposition instructions) from the agent 216. The interaction between the simulation environment 204 and the agent 216 can iterate until the simulation is stopped.

In some embodiments, the simulation environment 204 comprises a set of driver/rider behavior models 206 and historical real-data 214. The set of driver/rider behavior models 206 includes a driver movement model 208, a driver online-offline model 210, and a rider trip cancellation prediction model 212.

In some embodiments, the historical real-data 214 can include real historical orders placed for some specific dates, which formulates open trip orders in the simulation environment 204. The historical real-data 214 can also include sample snapshots of historical driver distribution throughout a geographical area at a specific time. The historical real-data 214 can also serve as training data for the set of driver/rider behavior models 206.

In some embodiments, the driver movement model 208 is a machine learning model trained to predict a destination of an idle driver. The driver movement model 208 can be any type of machine learning models, e.g., a tree-based model.

In some embodiments, drivers can choose time frame when they would like to provide transportation services. When a driver is providing services, his/her status is considered online. When the driver stops providing services, his/her status is considered offline. When a driver is offline, he/her is not considered to be in a driver pool in which a driver is classified as in either a “busy” state or an “idle” state. In the simulation environment 204, the online-offline operation is iterated periodically, e.g., every five minutes.

The driver online-offline model 210 is a machine learning model trained based on a number of historical online drivers, a number of historical offline drivers, and a number of simulated offline drivers.

In some embodiments, a geographical area can be divided into a number of grids. For an offline operation, a number of drivers in a grid within the simulation environment may be converted to an offline state based on the following formula:

K_{off}=min(num_dri_simu,num_offline_his)

where num_dri_simu denotes a number of idle drivers in the grid within the simulation environment, and num_offline_his denotes a number of historical offline drivers in the geographic location corresponding to this grid (e.g., learned from the historical data). The offline drivers are randomly sampled from idle drivers in this grid to perform offline procedure (e.g., being converted into the offline state). For an online operation, for each grid, a number of drivers may be converted to an online state based on the following formula:

$${K}_{o n} = num\_online \_his ⋆ \frac{{N}_{total \_ simu \_ offline}}{{N}_{total \_ his \_ offline}}$$

where num_offline_his denotes a number of historical online drivers in the geographic location corresponding to the grid (e.g., learned from the historical data), N_{total_simu_offline} denotes a number of total offline drivers in the simulation environment in the grid, and N_{total_his_offline} denotes a number of total historical offline drivers in the geographical area corresponding to the grid. The location of an online driver is at the center of the grid.

In some embodiments, the rider trip cancellation model 212 is a machine learning model trained to predict an order's cancellation probability based on order features. The order features include at least one of: a start location of the order, a destination of the order, a current time of the order, a day of the week of the order, or a price quote for the order.

The order cancellation probability can be expressed as π(b=1|s), where s denotes a state of an order (i.e., the order features); b denotes a binary number indicating whether the order is canceled; and π denotes a probability function. When an order is canceled, the state of the order can be considered as positive examples, and b is set to 1. When an order is successfully completed, the state of the order can be considered as negative examples, and b is set to 0.

In some embodiments, a machine learning model can be trained to predict the cancellation probability of the order given the order features. The machine learning model can be a function π(s;θ), where s denotes the order features which are input to the machine learning model, θ denotes parameters of the machine learning model, and the output of the machine learning model is the predicted cancellation probability, i.e., π(s;θ).

Many types of machine learning models can be utilized for predicting the cancellation probability, e.g., a LightGBM decision tree model, a Logistic Regression model, Xgboost model, etc. Under normal circumstances, the LightGBM decision tree model performs better than other types of machine learning models.

The machine learning model can be trained based on training data selected from real historical data including historical canceled orders and historical completed orders over a specified time period. The training data can be selected based on a specified learning rate, a specified number of boosted trees to fit, a specified maximum number of tree leaves for base learners, and specified early stopping rounds. As an example, the specified time period can be one month, the specified learning rate can be 0.025, the specified number of boosted trees to fit can be 900, the specified maximum number of tree leaves for base learners can be 38, and the specified early stopping rounds can be 10.

In some embodiments, the parameters θ obtained from the training of the machine learning model can be further optimized by maximizing a log-likelihood of the order cancellation probability π(s;θ). The log-likelihood of the order cancellation probability can be calculated based on historical canceled orders used to train the machine learning model and can be expressed as:

L(θ)=Σᵢ₌₁^{N}[yᵢ log π(sᵢ; θ)+(1−yᵢ)log(1−π(sᵢ; θ))]

where yᵢ denotes the label of the i^{th} training sample from the training data, and π(sᵢ|θ) denotes the predicted cancellation probability of the i^{th} training sample having features sᵢ. By optimizing the log-likelihood L(θ) of the order cancellation probability, optimized parameters θ for the machine learning model can be obtained.

In some embodiments, the agent 216 can implement either or both the order-dispatching algorithm 218 and the driver repositioning algorithm 220. The order-dispatching algorithm 218 can be used to match idle drivers with open trip orders. The driver repositioning algorithm 220 can be used to deploy an idle driver (i.e., a vehicle) to a specific location where a future demand is anticipated at this location.

If the agent 216 chooses to implement only the order dispatching algorithm 218, then the simulation environment 204 uses a default repositioning algorithm, which is considered as a part of the simulation environment 204. If the agent 216 chooses to develop only the repositioning algorithm, then the simulation environment 204 uses a default dispatching algorithm, which is considered as a part of the simulation environment 204.

In some embodiments, to evaluate the performance of the order-dispatching algorithm 218, the agent 216 implements the order-dispatching algorithm 218 to determine an order-driver matching within a time window. The state information related to the open orders (i.e., trip requests) and available drivers can be passed to the agent. After the agent performs the order-driver matching, it returns the matching results to the simulator. This agent can be called periodically for each time window throughout a simulation day. The evaluation simulation can run over a duration of time, e.g. multiple days, for which the mean total GMV (Gross Merchandise Value) of successfully completed orders per unit time over a period of time can be computed as a score for the order-dispatching algorithm 218.

In some embodiments, to evaluate the performance of the driver repositioning algorithm 220, the agent 216 implements the repositioning algorithm 220 for a pre-selected group of drivers (i.e., vehicles) selected in the simulation environment 204. The simulation environment 204 periodically sends the state information of the selected group of drivers to the repositioning algorithm 220, which generates a specific destination for each driver. The evaluation simulation runs over a duration of time, e.g. multiple days, for which the mean individual income rate for the group over the whole simulation period can be computed as the score for the driver repositioning algorithm 220.

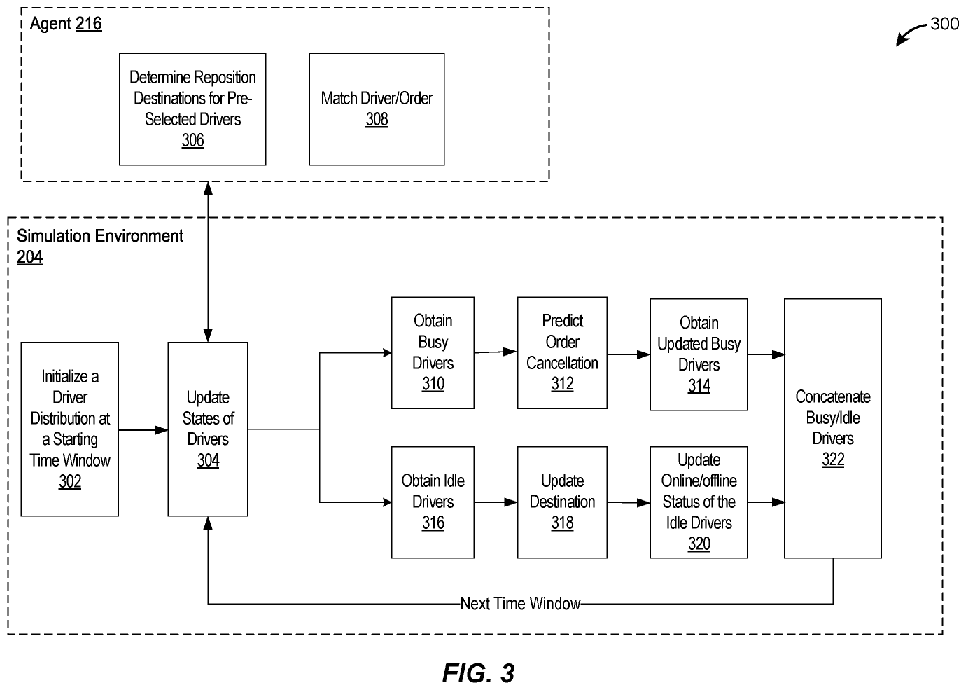

FIG. 3 illustrates an example workflow of the simulation framework for real time vehicle dispatching algorithms evaluation, in accordance with various embodiments of the disclosure. In the example workflow 300 of the simulation framework, the simulation environment 204 and the agent 216 interact in discrete time steps.

With respect to the workflow 300, at Block 302, the simulation environment 204 can initialize a driver distribution at a geographical area at a starting time (e.g., at 4 am) based on the historical driver distribution at the starting time extracted from driver distribution data files stored in a database. At each subsequent dispatching window, the simulator generates open trip orders based on orders at the same dispatching window in history. For example, a historical driver distribution can be recorded at 4 am of a specific day in a geographical area (e.g., San Francisco), which can be used to initialize the simulation environment 204. The simulation environment 204 can fetch and process raw data from Apache Hive using Apache Spark, and then generate simulation orders and driver distribution data.

With respect to the workflow 300, at Block 304, driver states are updated. In the simulation environment 204, driver movement behaviors are classified in two states, i.e., on-trip (busy) and random walk (idle). A group of drivers (i.e., vehicles) are pre-selected to be reposed in the simulation environment 204. Information about this reposed group of drivers and/or information about the driver states and order requests are sent to the agent 216, in which the order-dispatching algorithm and/or the driver reposition algorithm are implemented.

With respect to the workflow 300, at Block 306, the agent 216 determines reposition destination for each of pre-selected drivers using the driver reposition algorithm, and sends the reposition destinations to the simulation environment 204.

With respect to the workflow 300, at Block 308, the agent 216 can match drivers and order requests using the order-dispatching algorithm based on the received driver states and order requests, and sends back updated order/driver state information (i.e. “busy” or “idle”) to the simulation environment 204. Thus, information about busy drivers (i.e., matched drivers) can be obtained at Block 310, and information about idle drivers (i.e., unmatched drivers) can be obtained at Block 316.

With respect to the workflow 300, at Block 312, for a busy driver with a matched order, an order cancellation prediction can be performed in the simulation environment 204 based on the rider trip cancellation model 212 to predict if the matched order will be canceled. Based on the results of the order cancellation prediction, information about busy drivers can be updated at Block 314. For example, if the matched order is canceled by the rider, the state of the driver can be changed from “busy” to “idle”.

With respect to the workflow 300, at Block 318, for an idle driver (e.g., a driver without a matched order, or a driver with a canceled order), the driver destination will be updated in the simulation environment 204 based on the driver movement model 208.

With respect to the workflow 300, at Block 320, online/offline status of all idle drivers are updated in the simulation environment 204.

With respect to the workflow 300, at Block 322, information about busy drivers and idles drivers are concatenated. At this point, the work flow for the starting time window is finished. The information about busy drivers and idles drivers can be subsequently sent to Block 304 to update the states of all the drivers. Then, the simulation can go to a next time window, i.e., the example workflow 300 can be iterated for the next time window.

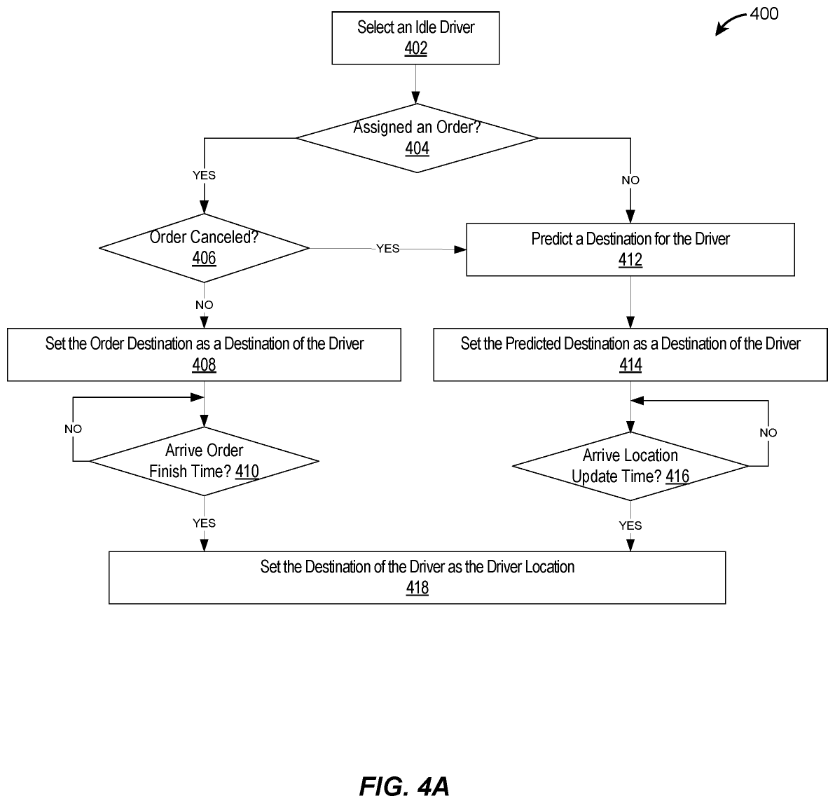

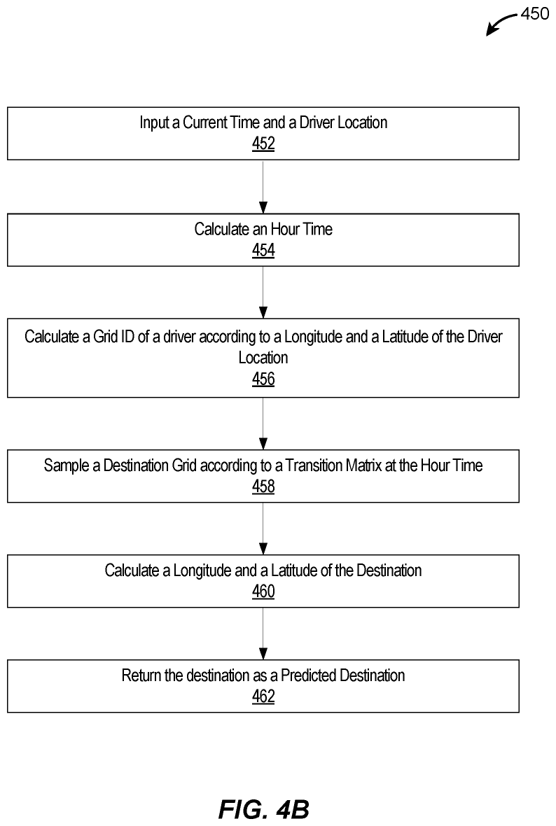

FIG. 4A illustrates a flowchart of an example method 400 for driver movement prediction, in accordance with various embodiments of the disclosure.

With respect to the method 400, at Block 402, a driver with an “idle” state is selected. At Block 404, a determination can be made whether the driver is assigned an order request.

At Block 406, if the driver is assigned an order request, a determination can be made whether the order request is canceled by a rider.

At Block 408, if the order request is not cancelled by the rider, the driver starts serving the order request, and the state of the driver can be changed from “idle” to “busy”. In this case, the order destination can be set as a destination of the driver.

At Block 410, a determination can be made whether the driver has arrived at the order destination. If the answer is no, the determination loops until the driver arrives at the destination. After dropping off the rider, the driver becomes “idle” and move around with a vacant vehicle.

At Block 412, if the driver is not assigned an order request, a destination of the driver can be predicted based on the driver movement model 208.

At Block 414, the predicted destination can be set as a destination of the driver.

At Block 416, a determination can be made whether the driver has arrived at the predicted destination. If the answer is no, the determination loops until the driver arrives at the predicted destination.

At Block 418, if the driver has arrived at the order destination (for a busy driver) or the predicted destination (for an idle driver), the destination of the driver can be set as the location of the driver.

FIG. 4B illustrates a flowchart of an example method 450 for destination prediction of an idle driver, in accordance with various embodiments of the disclosure.

In some embodiments, a tree-based model alongside a statistic of historical driver movement can be used to predict the destination of an idle driver. A probability of a transition from one grid of a geographical area to other grids at a next time slice under different situation (such as at different hour time) can be determined based on the grids. As an example, a time slice can be five minutes.

In some embodiments, a transition matrix can be created based on the probabilities of a transition from one grid to other grids at the next time slice. Table 1 below illustrates an example transition matrix having four columns: hour time, starting grid ID, finishing grid ID, and transition probability.

TABLE 1

| hour | Start_grid | Finish_grid | Probability |
|---|---|---|---|
| 0 | Grid1 | Grid1 | 0.3 |
| 0 | Grid1 | Grid2 | 0.7 |
| 0 | Grid2 | Grid2 | 0.6 |
| 0 | Grid2 | Grid1 | 0.4 |

According to Table 1, at hour time 0, for an idle driver in Grid1, at the next time slice (e.g., after five minutes), the probability of the driver staying at Grid1 is 0.3, and the probability of the driver transferring to Grid2 is 0.7. For an idle driver in Grid2, at the next time slice (e.g., after five minutes), the probability of the driver staying at Grid2 is 0.6, and the probability of the driver transferring to Grid1 is 0.4.

With respect to the method 400, at Block 452, a current time and a driver location are inputted.

At Block 454, an hour time is calculated based on the current time. The hour time is the whole number of the hour of the current time. For example, for a current time at 0:15, the hour time is 0; for a current time at 20:30, the hour time is 20.

At Block 456, a grid ID of a driver is calculated according to a GPS coordinates pair (longitude and latitude) of the driver location.

At Block 458, a destination grid is sampled according to the transition matrix at the hour time.

At Block 460, a longitude and a latitude of the destination grid is calculated.

At Block 462, the longitude and latitude of the destination is returned as a predicted destination.

Method for Building a Simulation Framework for Algorithms Evaluation

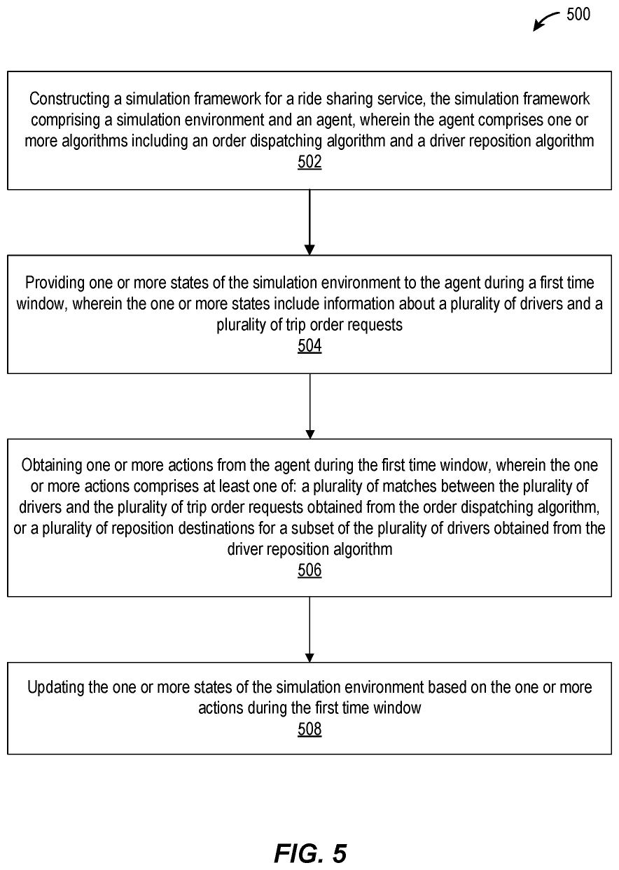

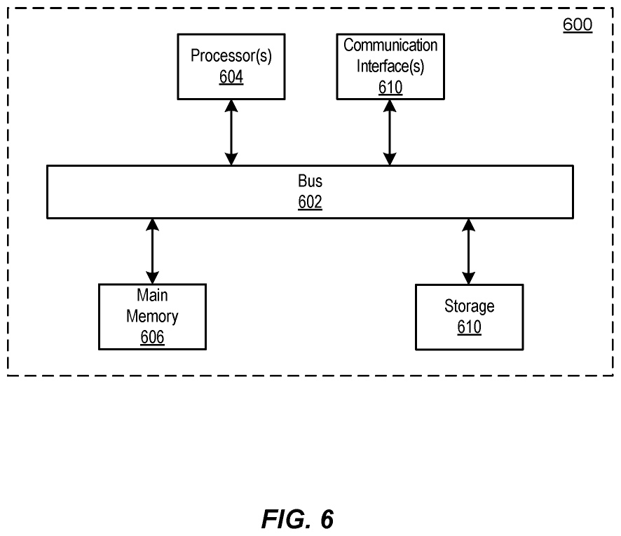

FIG. 5 illustrates a flowchart of an example method for simulation framework construction, in accordance with various embodiments of the disclosure. The method 500 can be implemented in various environments, e.g., the computer system 600 of FIG. 6. The operations of the method 500 presented below are intended to be illustrative. Depending on the implementation, the method 500 can include additional, fewer, or alternative steps performed in various orders or in parallel. The method 500 can be implemented in various computing systems or devices including one or more processors.

With respect to the method 500, at block 502, a computing system (e.g., the computer system 600 of FIG. 6) can construct a simulation framework for a ride sharing service. The simulation framework comprises a simulation environment and an agent. The agent comprises one or more algorithms including an order dispatching algorithm and a driver reposition algorithm.

With respect to the method 500, at block 504, the computer system can provide one or more states of the simulation environment to the agent during a first time window. The one or more states include information about a plurality of drivers and a plurality of trip order requests.

With respect to the method 500, at block 506, the computer system can obtain one or more actions from the agent during the first time window. The one or more actions comprise at least one of: a plurality of matches between the plurality of drivers and the plurality of trip order requests obtained from the order dispatching algorithm, or a plurality of reposition destinations for a subset of the plurality of drivers obtained from the driver reposition algorithm.

With respect to the method 500, at block 508, the computer system can update the one or more states of the simulation environment based on the one or more actions during the first time window.

Computer System

FIG. 6 is a block diagram that illustrates a computer system 600 upon which any of the embodiments described herein may be implemented. The computer system 600 includes a bus 602 or other communication mechanisms for communicating information, one or more hardware processors 604 coupled with bus 602 for processing information. Hardware processor(s) 604 may be, for example, one or more general-purpose microprocessors.

The computer system 600 also includes a main memory 606, such as a random access memory (RAM), cache and/or other dynamic storage devices, coupled to bus 602 for storing information and instructions to be executed by processor(s) 604. Main memory 606 also may be used for storing temporary variables or other intermediate information during execution of instructions to be executed by processor(s) 604. Such instructions, when stored in storage media accessible to processor(s) 604, render computer system 600 into a special-purpose machine that is customized to perform the operations specified in the instructions. Main memory 606 may include non-volatile media and/or volatile media. Non-volatile media may include, for example, optical or magnetic disks. Volatile media may include dynamic memory. Common forms of media may include, for example, a floppy disk, a flexible disk, hard disk, solid state drive, magnetic tape, or any other magnetic data storage medium, a CD-ROM, any other optical data storage medium, any physical medium with patterns of holes, a RAM, a DRAM, a PROM, and EPROM, a FLASH-EPROM, NVRAM, any other memory chip or cartridge, and networked versions of the same.

The computer system 600 may implement the techniques described herein using customized hard-wired logic, one or more ASICs or FPGAs, firmware and/or program logic which in combination with the computer system causes or programs computer system 600 to be a special-purpose machine. According to one embodiment, the techniques herein are performed by computer system 600 in response to processor(s) 604 executing one or more sequences of one or more instructions contained in main memory 606. Such instructions may be read into main memory 606 from another storage medium, such as storage device 608. Execution of the sequences of instructions contained in main memory 606 causes processor(s) 604 to perform the process steps described herein. For example, the process/method shown in FIGS. 5A-5B and described in connection with this figure may be implemented by computer program instructions stored in main memory 606. When these instructions are executed by processor(s) 604, they may perform the steps as shown in FIGS. 5A-5B and described above. In alternative embodiments, hard-wired circuitry may be used in place of or in combination with software instructions.

The computer system 600 also includes a communication interface 610 coupled to bus 602. Communication interface 610 provides a two-way data communication coupling to one or more network links that are connected to one or more networks. As another example, communication interface 610 may be a local area network (LAN) card to provide a data communication connection to a compatible LAN (or WAN component to communicated with a WAN). Wireless links may also be implemented.

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Certain embodiments are described herein as including logic or a number of components. Components may constitute either software components (e.g., code embodied on a machine-readable medium) or hardware components (e.g., a tangible unit capable of performing certain operations which may be configured or arranged in a certain physical manner). As used herein, for convenience, components of the computing system 202 may be described as performing or configured for performing an operation, when the components may comprise instructions which may program or configure the computing system 202 to perform the operation.

While examples and features of disclosed principles are described herein, modifications, adaptations, and other implementations are possible without departing from the spirit and scope of the disclosed embodiments. Also, the words “comprising,” “having,” “containing,” and “including,” and other similar forms are equivalent in meaning and be open ended in that an item or items following any of these words is not meant to be an exhaustive listing of such item or items, or meant to be limited to only the listed item or items. It must also be noted that as used herein and in the appended claims, the singular forms “a,” “an,” and “the” include plural references unless the context dictates otherwise.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

What is claimed is:

1. A method, comprising:
constructing, by a computer system, a simulation framework for a ride sharing service, the simulation framework comprising a simulation environment and an agent, wherein the agent comprises one or more algorithms including an order dispatching algorithm and a driver reposition algorithm;
providing, by the computer system, one or more states of the simulation environment to the agent during a first time window, wherein the one or more states include information about a plurality of drivers and a plurality of trip order requests;
obtaining, by the computer system, one or more actions from the agent during the first time window, wherein the one or more actions comprise at least one of:
a plurality of matches between the plurality of drivers and the plurality of trip order requests obtained from the order dispatching algorithm, or a plurality of reposition destinations for a subset of the plurality of drivers obtained from the driver reposition algorithm; and
updating, by the computer system, the one or more states of the simulation environment based on the one or more actions during the first time window.

2. The method of claim 1, further comprising:
iterating, by the computer system, the providing the one or more states of the simulation environment to the agent, the obtaining the one or more actions from the agent, and the updating the one or more states during a second time window.

3. The method of claim 1, further comprising:
initializing, by the computer system, the simulation environment during the first time window, wherein the initializing comprises initializing a driver distribution of the plurality of drivers in a geographical area at a starting time of the first time window.

4. The method of claim 1, further comprising:
evaluating, by the computer system, performance of the one or more algorithms, wherein the evaluating comprises at least one of:
determining a score for the order dispatching algorithm based on a mean total GMV (Gross Merchandise Value) of successful completed orders per unit time over a period of time; or
determining a score for the driver reposition algorithm based on a mean individual income rate for a group of drivers over a period of time.

5. The method of claim 1, wherein the simulation environment includes historical real data and a set of user behavior models trained based on the historical real data, wherein the set of user behavior models comprises a driver movement model, a driver online-offline model, and a rider trip cancellation model.

6. The method of claim 5, wherein the updating the one or more states of the simulation environment further comprises:
predicting, by the computer system, whether a matched order will be canceled based on the rider trip cancellation model;
predicting, by the computer system, a destination of an idle driver based on the driver movement model and statistics of historical driver movement; and
updating, by the computer system, the information about the plurality of idle drivers and the plurality of trip order requests.

7. The method of claim 5, wherein the driver movement model is a tree-based machine learning model.

8. The method of claim 5, wherein the driver online-offline model is a machine learning model trained based on a number of historical online drivers, a number of historical offline drivers, and a number of simulated offline drivers.

9. The method of claim 5, wherein the rider trip cancellation model is a machine learning model trained to predict a cancellation probability of an order based on order features, wherein the order features include at least one of: a start location of the order, a destination of the order, a current time of the order, a day of the week of the order, or a price quote for the order.

10. The method of claim 9, further comprising training the rider trip cancellation model based on training data generated based on a plurality of historical canceled orders and a plurality of successfully completed orders.

11. The method of claim 5, wherein the rider trip cancellation model is a LightGBM (Light Gradient Boosting Machine) decision tree model.

12. A system comprising:
at least one processor; and
a memory storing instructions that, when executed by the at least one processor, cause the system to perform operations comprising:
constructing a simulation framework for a ride sharing service, the simulation framework comprising a simulation environment and an agent, wherein the agent comprises one or more algorithms including an order dispatching algorithm and a driver reposition algorithm;
providing one or more states of the simulation environment to the agent during a first time window, wherein the one or more states include information about a plurality of drivers and a plurality of trip order requests;
obtaining one or more actions from the agent during the first time window, wherein the one or more actions comprise at least one of: a plurality of matches between the plurality of drivers and the plurality of trip order requests obtained from the order dispatching algorithm, or a plurality of reposition destinations for a subset of the plurality of drivers obtained from the driver reposition algorithm; and
updating the one or more states of the simulation environment based on the one or more actions during the first time window.

13. The system of claim 12, wherein the operations further comprises:
iterating the providing the one or more states of the simulation environment to the agent, the obtaining the one or more actions from the agent, and the updating the one or more states during a second time window.

14. The system of claim 12, wherein the operations further comprises:
initializing the simulation environment during the first time window, wherein the initializing comprises initializing a driver distribution of the plurality of drivers in a geographical area at a starting time of the first time window.

15. The system of claim 12, wherein the operations further comprises:
evaluating performance of the one or more algorithms, wherein the evaluating comprises at least one of:
determining a score for the order dispatching algorithm based on a mean total GMV (Gross Merchandise Value) of successful completed orders per unit time over a period of time; or
determining a score for the driver reposition algorithm based on a mean individual income rate for a group of drivers over a period of time.

16. The system of claim 12, wherein the simulation environment includes historical real data and a set of user behavior models trained based on the historical real data, wherein the set of user behavior models comprises a driver movement model, a driver online-offline model, and a rider trip cancellation model.

17. A non-transitory computer-readable storage medium including instructions that, when executed by at least one processor of a computer system, cause the computer system to perform operations comprising:
constructing a simulation framework for a ride sharing service, the simulation framework comprising a simulation environment and an agent, wherein the agent comprises one or more algorithms including an order dispatching algorithm and a driver reposition algorithm;
providing one or more states of the simulation environment to the agent during a first time window, wherein the one or more states include information about a plurality of drivers and a plurality of trip order requests;
obtaining one or more actions from the agent during the first time window, wherein the one or more actions comprise at least one of: a plurality of matches between the plurality of drivers and the plurality of trip order requests obtained from the order dispatching algorithm, or a plurality of reposition destinations for a subset of the plurality of drivers obtained from the driver reposition algorithm; and
updating the one or more states of the simulation environment based on the one or more actions during the first time window.

18. The non-transitory computer-readable storage medium of claim 17, wherein the operations further comprises:
iterating the providing the one or more states of the simulation environment to the agent, the obtaining the one or more actions from the agent, and the updating the one or more states during a second time window.

19. The non-transitory computer-readable storage medium of claim 17, wherein the operations further comprises:
initializing the simulation environment during the first time window, wherein the initializing comprises initializing a driver distribution of the plurality of drivers in a geographical area at a starting time of the first time window.

20. The non-transitory computer-readable storage medium of claim 17, wherein the operations further comprises:
evaluating performance of the one or more algorithms, wherein the evaluating comprises at least one of:
determining a score for the order dispatching algorithm based on a mean total GMV (Gross Merchandise Value) of successful completed orders per unit time over a period of time; or
determining a score for the driver reposition algorithm based on a mean individual income rate for a group of drivers over a period of time.
